(19) United States
(12) Patent Application Publication
(10) Pub. No.: US 2013/0126824 A1
(43) Pub. Date: May 23, 2013

(54) SEMICONDUCTIVE NANOWIRE SOLID STATE OPTICAL DEVICE AND CONTROL METHOD THEREOF

(71) Applicants: YU-CHING SHIH, Taipei (TW); Jiunn-horng Lee, Taipei (TW); Chia-chin Chen, Taipei (TW); Chi-feng Lin, Taipei (TW); Yu-bin Fang, Taipei (TW); Ming-hsiao Lee, Taipei (TW); Heng-chuan Kan, Taipei (TW)

(72) Inventors: YU-CHING SHIH, Taipei (TW); Jiunn-horng Lee, Taipei (TW); Chia-chin Chen, Taipei (TW); Chi-feng Lin, Taipei (TW); Yu-bin Fang, Taipei (TW); Ming-hsiao Lee, Taipei (TW); Heng-chuan Kan, Taipei (TW)

(73) Assignee: National Applied Research Laboratories, Taipei City (TW)

(21) Appl. No.: 13/527,447

(22) Filed: Jun. 19, 2012

(30) Foreign Application Priority Data
Nov. 18, 2011 (TW) 100142417

(51) Int. Cl. H01L 33/06; H01L 31/0352; B82Y 20/00

(52) U.S. Cl. 257/9; 257/E33.006; 257/E31.038; 977/762; 977/948; 977/950

(57) ABSTRACT

Disclosed are a semiconductor nanowire solid state optical device and a control method thereof. The device comprises a nanowire, a first electrode, a second electrode, an electrical circuit and a mechanical micro device. The nanowire has a first end and a second end. The first electrode is coupled to the first end. The second electrode is coupled to the second end. The electrical circuit is coupled to the first electrode and the second electrode. The mechanical micro device is conjuncted with the nanowire for applying an external force to the nanowire to form highest occupied molecular orbital (HOMO) and lowest unoccupied molecular orbital (LUMO) in the nanowire. The HOMO and LUMO are employed as an n-type semiconductor and a p-type semiconductor, respectively. The nanowire is a semiconductor when an external force is applied thereto.

### BACKGROUND OF THE INVENTION

1. Field of the Invention

The present invention generally relates to a semiconductor nanowire solid state optical device, and more particularly to a semiconductor nanowire solid state optical device for being an electroluminescence device or a photovoltaic device and control method thereof.

2. Description of Prior Art

The harshest challenge of human beings today is to think through a way of eternal survive in the future. Kinds of topics, such as rapid global population growth, global warming, climate change, lack of basic survive resource and serious pollution of the earth environment and etc. are all severe predicaments that the human beings have to face and deal with. As regarding the topics of deficient energy, the ascendant solar energy and LED industries may be considered as the solutions of solving the deficient energy for the human beings in the future and therefore become important and major possibilities. Today, products of related industries have been developed and progressed toward the nano scale and semiconductor manufacture processes are applied for fabricating the p-type semiconductor and an n-type semiconductor required in a photovoltaic device or in an electroluminescence device.

As revealed in Nanoscale coherent optical components of U.S. Pat. No. 7,254,151, a doping process is required for fabricating the PN interface necessary in a luminous element.

As revealed in Nanowire light emitting device and method of fabricating the same of U.S. Pat. No. 7,435,996, a doping process is required for fabricating the PN interface necessary in a luminous element.

As revealed in Light emitting nanowires for macroelectronics of US Patent Publication 2006/0273328, a fabrication process of heterostructure is required for fabricating the PN interface necessary in a luminous element.

As revealed in Method for manufacturing super bright light emitting diode of nanorod array having InGaN quantum well of U.S. Pat. No. 7,396,696, a doping process is required for fabricating the PN interface necessary in a luminous element.

As revealed in Light emitting diode employing an array of nanorods and method of fabricating the same of U.S. Pat. No. 7,816,700, a doping process is required for fabricating the PN interface necessary in a luminous element.

As revealed in Nanowire devices and systems, light-emitting nanowires, and methods of precisely positioning nanoparticles of U.S. Pat. No. 7,910,915, a doping process is required for fabricating the PN interface necessary in a luminous element.

As revealed in Nanowire-based light-emitting diodes and light-detection devices with nanocrystalline outer surface of U.S. Pat. No. 7,863,625, a doping process is required for fabricating the PN interface necessary in a luminous element.

As revealed in Nanostructure and photovoltaic cell implementing same of U.S. Pat. No. 7,847,180, a fabrication process of heterostructure is required for fabricating the PN interface necessary in a photovoltaic device.

As revealed in Nanowire heterostructures and Apparatus and methods for solar energy conversion using nanoscale cometal structures of U.S. Pat. Nos. 7,858,965 and 7,943,847, a fabrication process of heterostructure is required for fabricating the PN interface necessary in a luminous element.

As aforementioned, As regarding the fabrication of the p-type semiconductor and the n-type semiconductor required in various photovoltaic devices and electroluminescence devices, a doping process or a fabrication process of heterostructure is generally utilized in related industries nowadays.

### SUMMARY OF THE INVENTION

An objective of the present invention is to provide a semiconductor nanowire solid state optical device, comprising a nanowire, having a first end and a second end; a first electrode, coupled to the first end; a second electrode, coupled to the second end; an electrical circuit, coupled to the first electrode and the second electrode; a mechanical micro device, conjuncted with the nanowire for applying an external force thereto to form highest occupied molecular orbital and lowest unoccupied molecular orbital in the nanowire. The nanowire is fabricated by a single material. For instance, the material of the nanowire is selected from group 2 elements, triels, tetrels and pentels. The nanowire may have silicon nano-crystal structure and the direction of the silicon nano-crystal structure.

The mechanical micro device applies the external force to twist the nanowire. When the mechanical micro device twist the nanowire, the highest occupied molecular orbital and the lowest unoccupied molecular orbital become an n-type semiconductor and a p-type semiconductor, respectively. Therefore, as the nanowire is applied with the external force, the nanowire is becomes a semiconductor and capable of being employed as a photovoltaic device or an electroluminescence device.

The present invention also provides a control method of a semiconductor nanowire solid state optical device and the semiconductor nanowire solid state optical device comprises a nanowire, an electrical circuit and a mechanical micro device, which is conjuncted with the nanowire. The control method comprises applying an external force to the nanowire by the mechanical micro device to form highest occupied molecular orbital and lowest unoccupied molecular orbital in the nanowire.

According to the present invention, the nanowire can be employed as an electroluminescence device. The control method of the present invention further comprises a step of applying electrical power to the nanowire for causing the nanowire illuminate.

According to the present invention, the nanowire can be employed as a photovoltaic device. The control method of the present invention further comprises a step of a step of shining the nanowire with light to cause the nanowire to generate an electric current.

The semiconductor nanowire solid state optical device and the control method of present invention does not require doping or fabrication of heterostructure to form a semiconductor optical device with a PN interface which is necessary in prior arts. The present invention merely applies an external force, such as twisting the nanowire and the nanowire can become a semiconductor with a PN interface. The mechanical micro device is employed as a switch of the semiconductor solid state optical device according to the present invention. Once the external force applied to the nanowire is erased, the solid state optical device of the present invention, which is employed as a photovoltaic device or an electroluminescence device stop its function.

### BRIEF DESCRIPTION OF THE DRAWINGS

FIG. 1 depicts a simple diagram of a semiconductive photovoltaic device;

FIG. 2 depicts a simple diagram of semiconductive electroluminescence;

FIG. 3 depicts a simple diagram of a semiconductor nanowire solid state optical device according to the present invention;

FIG. 4A to FIG. 4D show a semiconductor nanowire solid state optical device of the present invention in a non-twisted state;

FIG. 5A to FIG. 5D show front view distribution diagrams and sectional diagrams of lowest unoccupied molecular orbital (LUMO) and highest occupied molecular orbital (HOMO) with certain twist angles according to a first embodiment of the present invention;

FIG. 6A to FIG. 6C show front view distribution diagrams and a sectional diagram of lowest unoccupied molecular orbital (LUMO) and highest occupied molecular orbital (HOMO) with certain twist angles according to a second embodiment of the present invention;

FIG. 7A to FIG. 7C show front view distribution diagrams and a sectional diagram of lowest unoccupied molecular orbital (LUMO) and highest occupied molecular orbital (HOMO) with certain twist angles according to a third embodiment of the present invention;

FIG. 8A and FIG. 8B show flowcharts of embodiments according to the control methods of the semiconductor nanowire solid state optical device of the present invention.

### DETAILED DESCRIPTION OF THE INVENTION

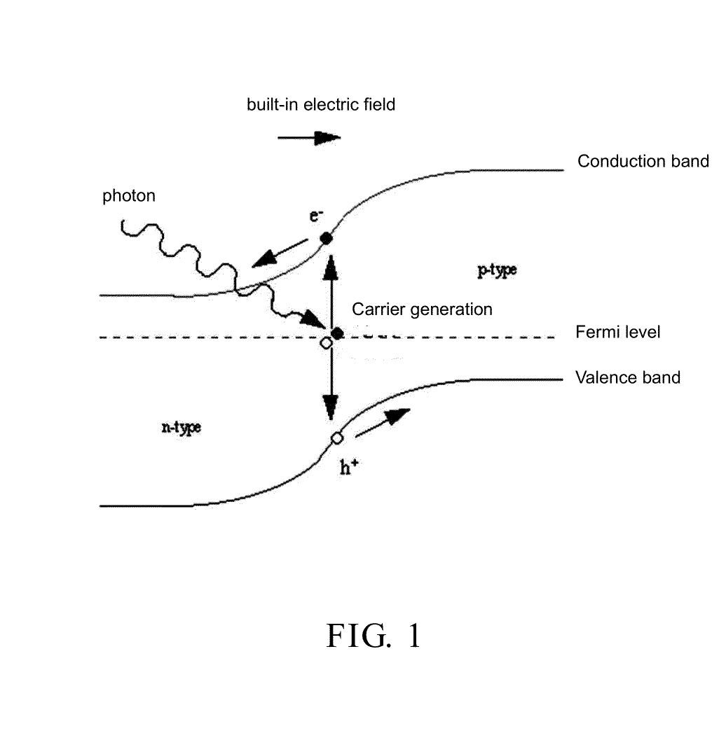

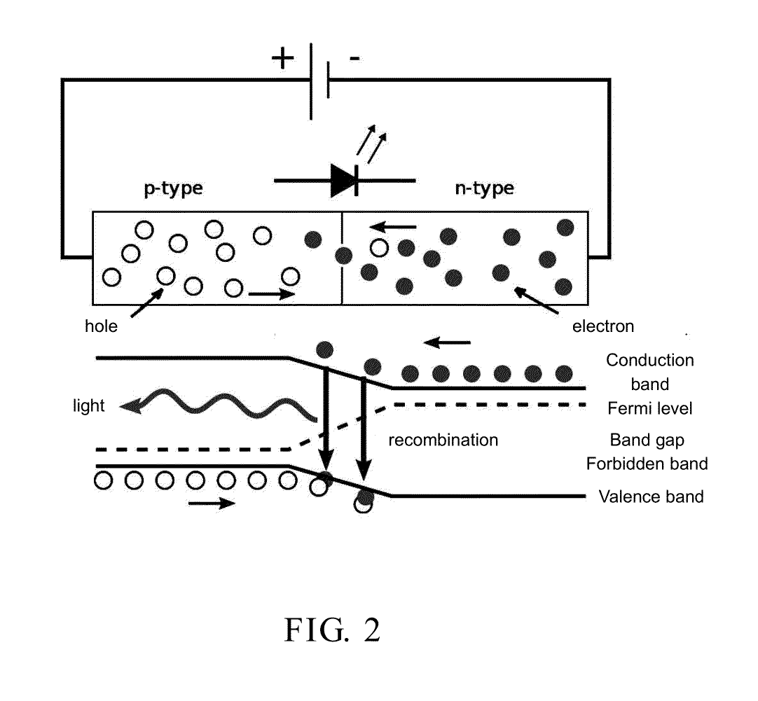

Please refer to FIG. 1, which depicts a simple diagram of a semiconductive photovoltaic device. Please refer to FIG. 2, which depicts a simple diagram of semiconductive electroluminescence. The photovoltaic device in FIG. 1 comprises a p-type semiconductor and an n-type semiconductor, which a PN interface exists therebetween. As the photovoltaic device accepts a photon, the energy provided by the photon excites an electron in the semiconductor and generates electron-electron hole at the PN interface. The built-in electric field separates the electron-electron hole before their combination and generates a photocurrent. The semiconductive electroluminescence device shown in FIG. 2 comprises a p-type semiconductor and a n-type semiconductor, which a PN interface exists therebetween. A power is applied to the electroluminescence device for forward biasing. The electron of the conduction band and the electron hole of the valence band to be recombined, i.e. the electron of the n-type semiconductor is driven to the p-type semiconductor recombination of the electron and the electron hole occurs at the PN interface. The lost energy is outputted in form of light.

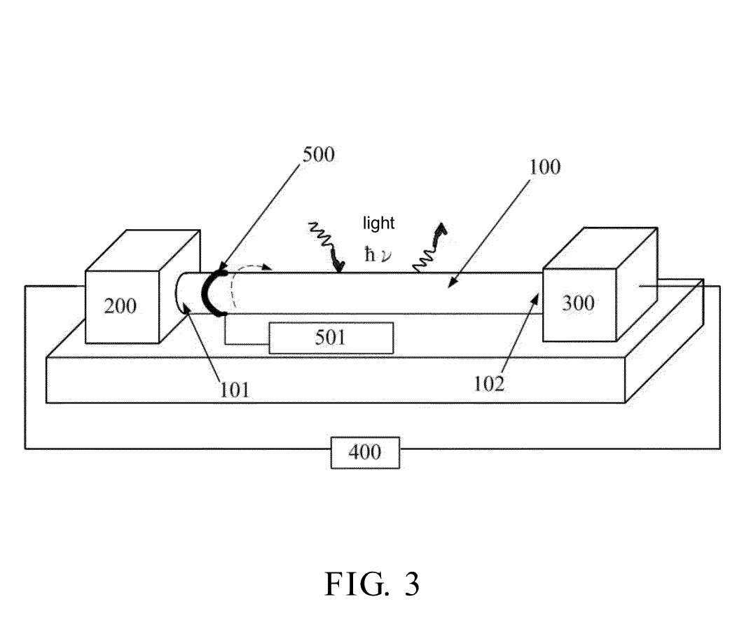

Please refer to FIG. 3, which depicts a simple diagram of a semiconductor nanowire solid state optical device according to the present invention. The semiconductor nanowire solid state optical device comprises a nanowire 100, a first electrode 200, a second electrode 300, an electrical circuit 400 and a mechanical micro device 500. The nanowire 100 has a first end 101 and a second end 102. The first electrode 200 is coupled to the first end 101. The second electrode 300 is coupled to the second end 102. The electrical circuit 400 is coupled to the first electrode 200 and the second electrode 300. The mechanical micro device 500 is coupled to a controller 501 to be controlled thereby and conjuncted with the nanowire 100 for applying an external force to the nanowire 100 to form highest occupied molecular orbital and lowest unoccupied molecular orbital in the nanowire (Detail is conducted later). The highest occupied molecular orbital (HOMO) and the lowest unoccupied molecular orbital (LUMO) may be employed as n-type semiconductor and p-type semiconductor respectively. When the nanowire 100 is in the state of being applied with the external force, the nanowire 100 becomes a semiconductor device. In the illustration of the present invention, the mechanical micro device 500 applies the external force to twist the nanowire 100, however, it is not a limitation to the present invention. To stretch or to compress the nanowire 100 also can be illustrated as long as the highest occupied molecular orbital (HOMO) and the lowest unoccupied molecular orbital (LUMO) can be formed in the nanowire 100. Moreover, in the illustration of the present invention, a microelectromechanical design can be illustrated as employed as the mechanical micro device 500 itself and the conjunction of the mechanical micro device 500 and the nanowire 100 for twisting the nanowire 100, however, it is not a limitation to the present invention.

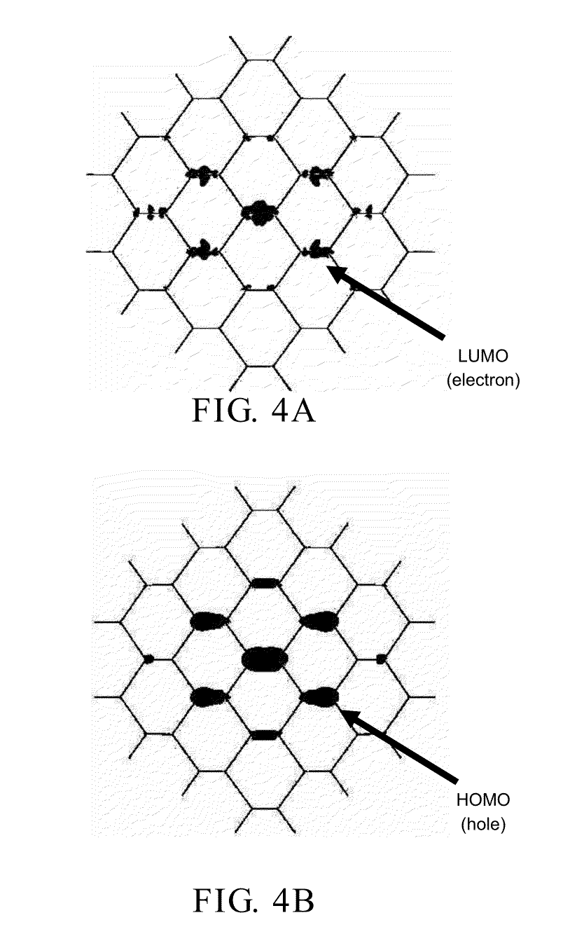

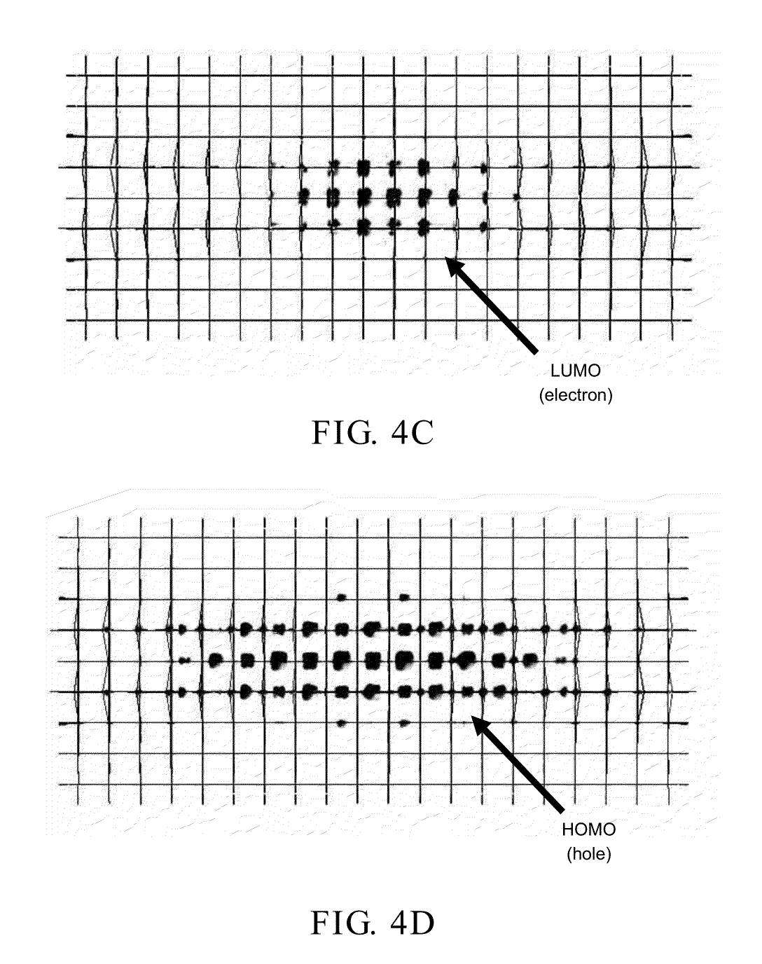

Please refer to FIG. 3, FIG. 4A to FIG. 4D, which show distribution diagrams of the highest occupied molecular orbital (HOMO) and the lowest unoccupied molecular orbital (LUMO) when the nanowire 100 is not applied with an external force, which represents that the semiconductor nanowire solid state optical device of the present invention in a non-twisted state by simulation software analysis. In this embodiment, the direction of the nano-crystal structure in the nanowire 100 is <110>. The diameter of the nanowire 100 is 1.5 nm. The nanowire 100 is a silicon nanowire which is fabricated by a single material and comprises silicon nano-crystal structures.

FIG. 4A and FIG. 4B show a front view diagram of the nanowire 100. FIG. 4C and FIG. 4D show a sectional view diagram of the nanowire 100. FIG. 4A and FIG. 4C show the electron distribution in the nanowire 100 when the external force is not applied thereto. FIG. 4B and FIG. 4D show the electron hole distribution in the nanowire 100 when the external force is not applied thereto. As shown in FIG. 4A to FIG. 4D, the position of the highest occupied molecular orbital (HOMO) and the position of the lowest unoccupied molecular orbital (LUMO) almost overlap as the nanowire 100 is not applied with an external force. The n-type semiconductor and the p-type semiconductor are not formed in the nanowire 100.

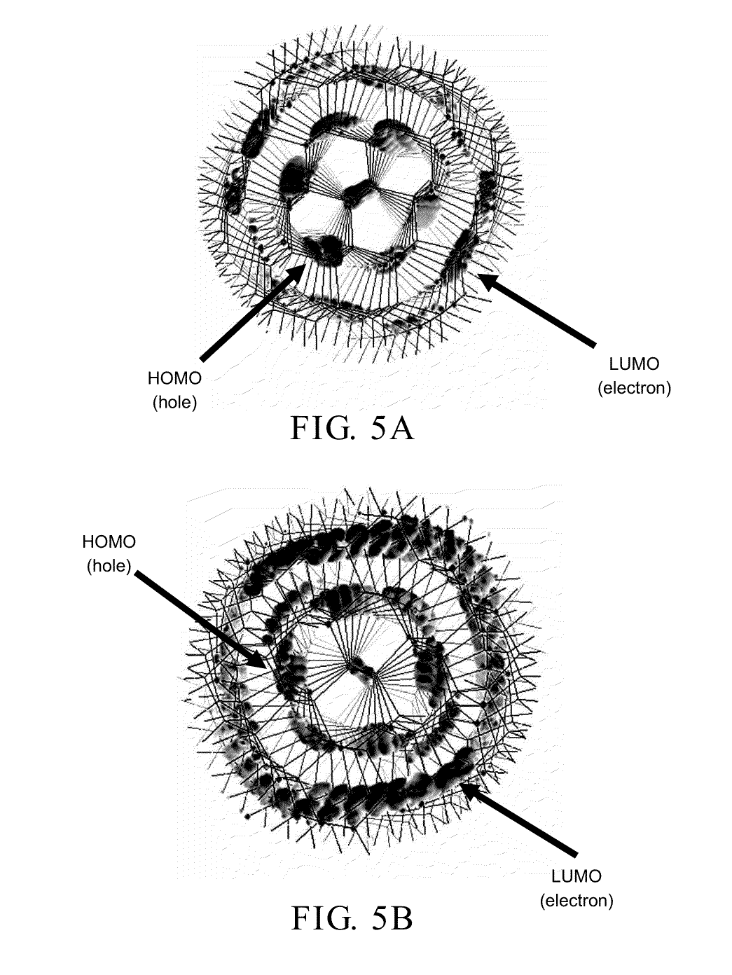

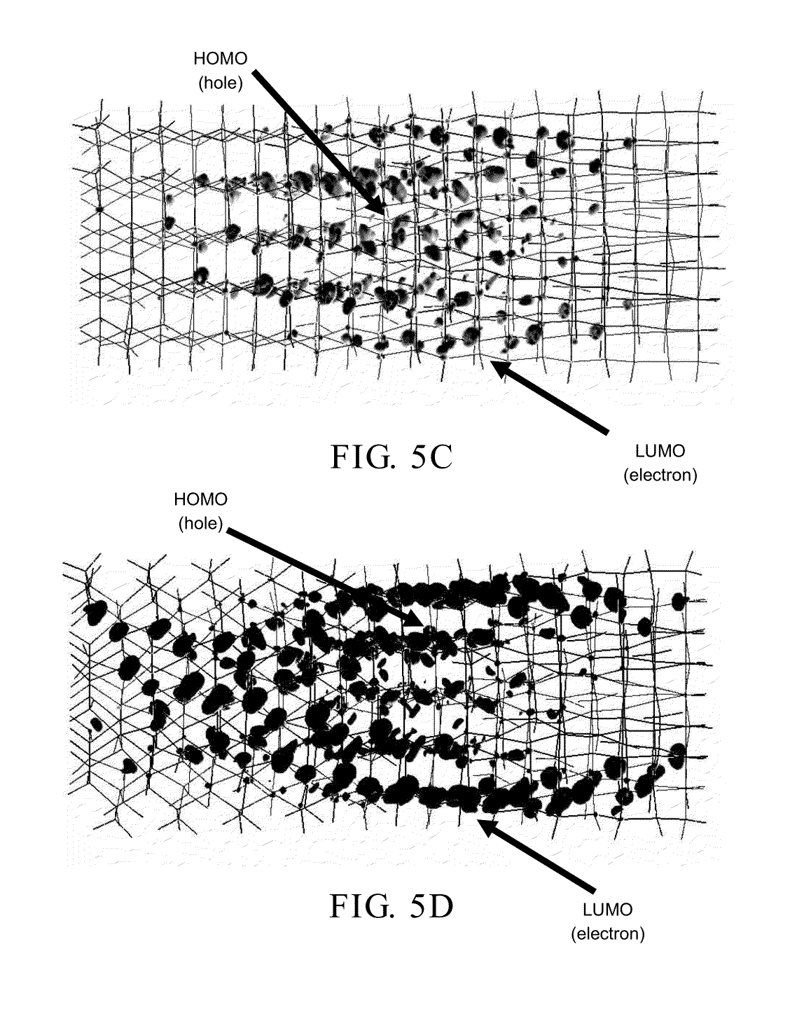

Please refer to FIG. 3, FIG. 5A to FIG. 5D, which show front view and sectional view relationship diagrams between the twist angle of the nanowire 100 according to the first embodiment of the present invention and the highest occupied molecular orbital (HOMO), the lowest unoccupied molecular orbital (LUMO) by simulation software analysis. In this embodiment, the direction of the nano-crystal structure in the nanowire 100 is <110>. The diameter of the nanowire 100 is 1.5 nm. The nanowire 100 is a silicon nanowire which is fabricated by a single material and comprises silicon nano-crystal structures. However, the present invention is not limited thereto. The material of the nanowire 100 can selected from group 2 elements, triels, tetrels and pentels.

FIG. 5A and FIG. 5B show a front view diagram of the nanowire 100. FIG. 5C and FIG. 5D show a sectional view diagram of the nanowire 100. FIG. 5A and FIG. 5C show the electron and electron hole distributions in the nanowire 100 when the mechanical micro device 500 applies the external force to twist the nanowire 100 of the present invention with 50 degrees. FIG. 5B and FIG. 5D show the electron and electron hole distributions in the nanowire 100 when the mechanical micro device 500 applies the external force to twist the nanowire 100 of the present invention with 87.5 degrees. As shown in FIG. 5A to FIG. 5D, when the twist angle is larger, the trend is more obvious that the lowest unoccupied molecular orbital (LUMO) is formed at the outer periphery of the nanowire 100 and the highest occupied molecular orbital (HOMO) is formed at the center of the nanowire 100. Therefore, the nanowire 100 can be turned into a semiconductor with a PN interface. Furthermore, the mechanical micro device 500 can be employed as a switch of the semiconductor nanowire solid state optical device in the present invention. The switching on and off of the semiconductor nanowire solid state optical device of the present invention can be controlled by manipulating the twist angle of the nanowire 100 with the mechanical micro device 500.

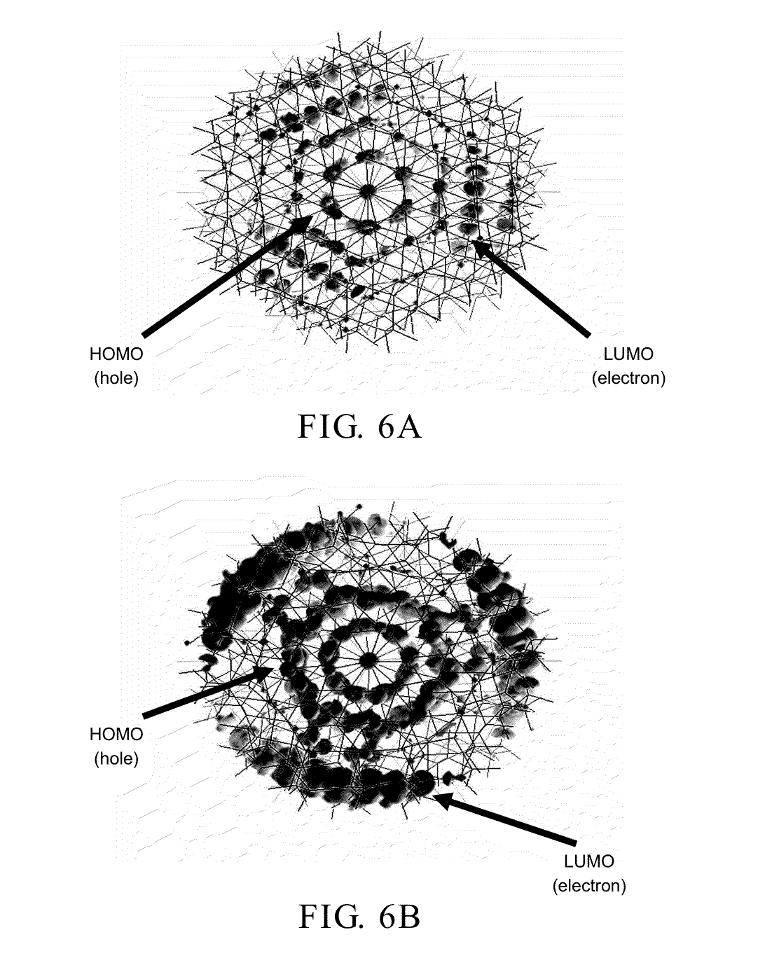

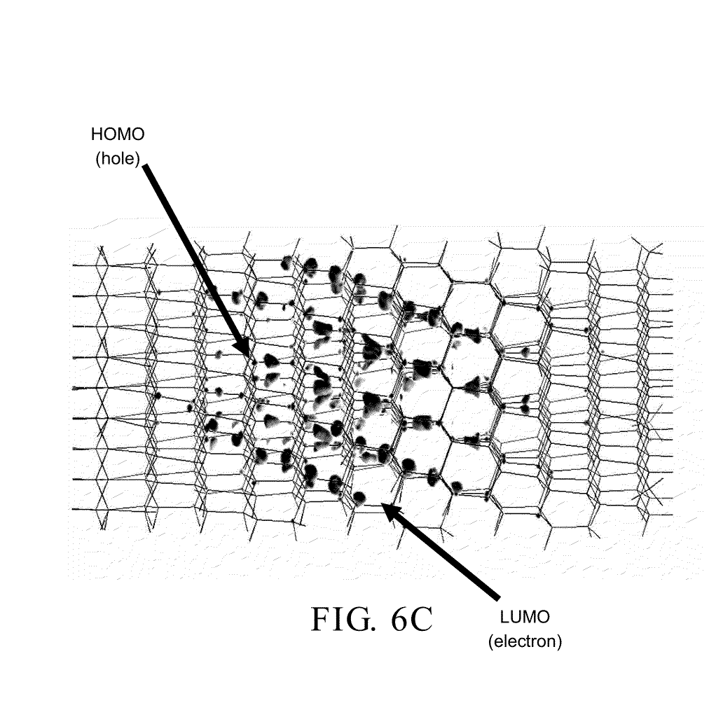

Please refer to FIG. 3, FIG. 6A to FIG. 6C, which show front view and sectional view relationship diagrams between the twist angle of the nanowire 100 according to the second embodiment of the present invention and the highest occupied molecular orbital (HOMO), the lowest unoccupied molecular orbital (LUMO) by simulation software analysis. In this embodiment, the direction of the nano-crystal structure in the nanowire 100 is <111>. The diameter of the nanowire 100 is 1.5 nm. The nanowire 100 is a silicon nanowire which is fabricated by a single material and comprises silicon nano-crystal structures. However, the present invention is not limited thereto. The material of the nanowire 100 can selected from group 2 elements, triels, tetrels and pentels.

FIG. 6A and FIG. 6B show a front view diagram of the nanowire 100. FIG. 6C shows a sectional view diagram of the nanowire 100. FIG. 6A and FIG. 6C show the electron and electron hole distributions in the nanowire 100 when the mechanical micro device 500 applies the external force to twist the nanowire 100 of the present invention with 50 degrees. FIG. 6B shows the electron and electron hole distributions in the nanowire 100 when the mechanical micro device 500 applies the external force to twist the nanowire 100 of the present invention with 87.5 degrees. As shown in FIG. 6A to FIG. 6C, when the twist angle is larger, the trend is more obvious that the lowest unoccupied molecular orbital (LUMO) is formed at the outer periphery of the nanowire 100 and the highest occupied molecular orbital (HOMO) is formed at the center of the nanowire 100. Furthermore, The switching on and off of the semiconductor nanowire solid state optical device of the present invention can be controlled by twisting nanowire 100 with the external force applied by the mechanical micro device 500 to turning the nanowire 100 into a semiconductor with a PN interface.

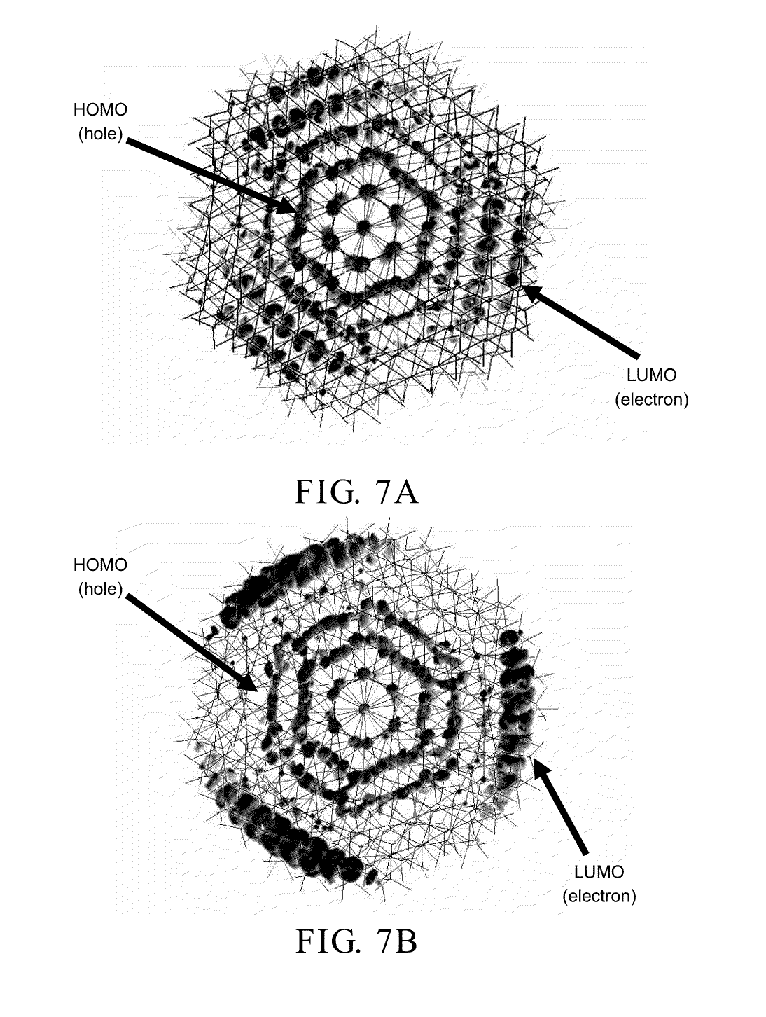

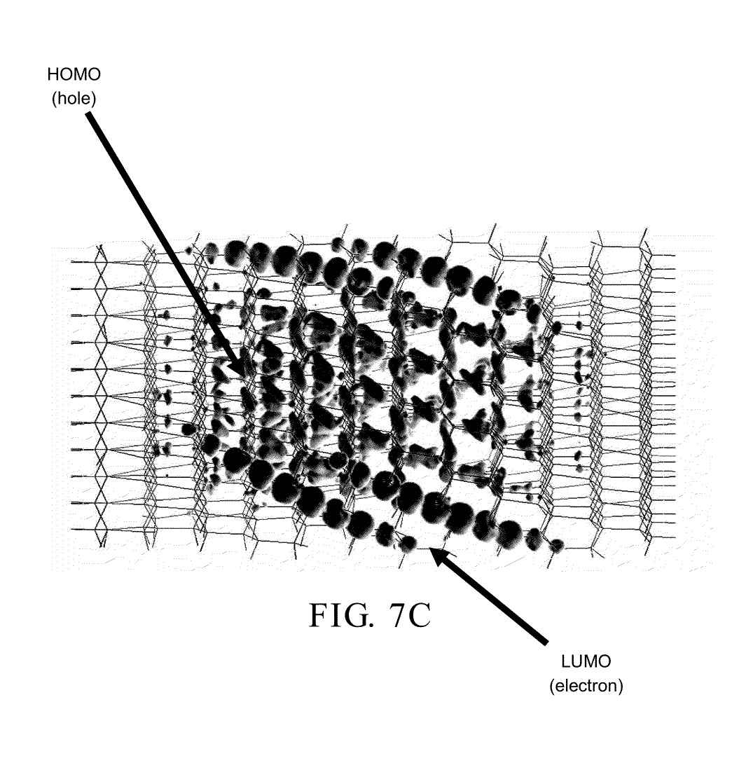

Please refer to FIG. 3, FIG. 7A to FIG. 7C, which show front view and sectional view relationship diagrams between the twist angle of the nanowire 100 according to the third embodiment of the present invention and the highest occupied molecular orbital (HOMO), the lowest unoccupied molecular orbital (LUMO) by simulation software analysis. In this embodiment, the direction of the nano-crystal structure in the nanowire 100 is <111>. The diameter of the nanowire 100 is 2.2 nm. The nanowire 100 is a silicon nanowire which is fabricated by a single material and comprises silicon nano-crystal structures. However, the present invention is not limited thereto. The material of the nanowire 100 can selected from group 2 elements, triels, tetrels and pentels.

FIG. 7A and FIG. 7B show a front view diagram of the nanowire 100. FIG. 7C shows a sectional view diagram of the nanowire 100. FIG. 7A shows the electron and electron hole distributions in the nanowire 100 when the mechanical micro device 500 applies the external force to twist the nanowire 100 of the present invention with 50 degrees. FIG. 7B and FIG. 7C show the electron and electron hole distributions in the nanowire 100 when the mechanical micro device 500 applies the external force to twist the nanowire 100 of the present invention with 87.5 degrees. As shown in FIG. 7A to FIG. 7C, when the twist angle is larger, the trend is more obvious that the lowest unoccupied molecular orbital (LUMO) is formed at the outer periphery of the nanowire 100 and the highest occupied molecular orbital (HOMO) is formed at the center of the nanowire 100. Furthermore, when the nanowire 100 with 2.2 nm diameter is used, the distributions of electron and the electron hole as employed as the n-type semiconductor and the p-type semiconductor are more distinguishable.

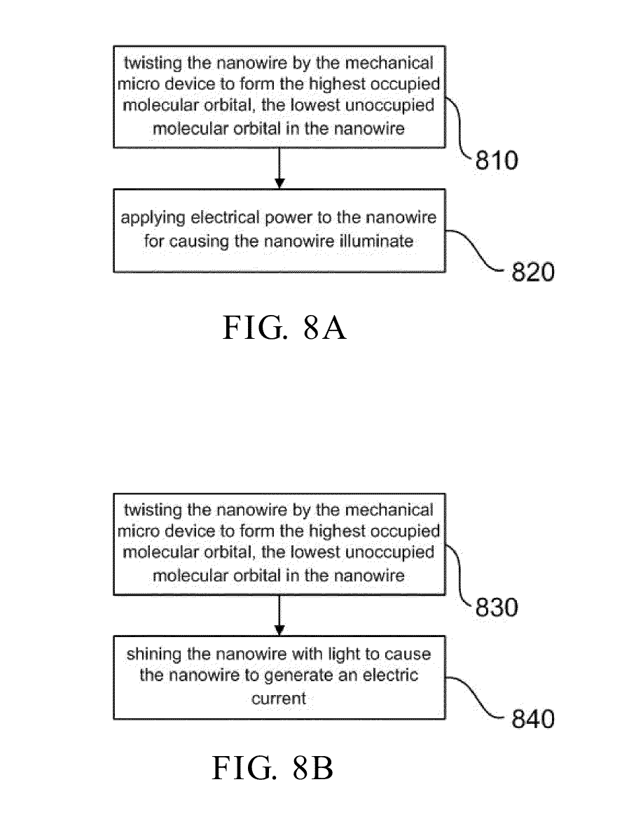

Please refer to FIG. 8A and FIG. 8B, which show flowcharts of embodiments according to the control methods of the semiconductor nanowire solid state optical device of the present invention.

As aforementioned, the semiconductor nanowire solid state optical device of the present invention can be employed as an electroluminescence device, such as a solid state light emitting device. Please refer to FIG. 2, FIG. 3 and FIG. 8A. In this embodiment, the control method of the semiconductor nanowire solid state optical device of the present invention comprises steps of:
Step 810, twisting the nanowire 100 by the mechanical micro device 500 to form the highest occupied molecular orbital (electron hole), the lowest unoccupied molecular orbital (electron) in the nanowire 100;
Step 820, applying electrical power to the nanowire 100 for causing the nanowire 100 illuminate.

As aforementioned, the semiconductor nanowire solid state optical device of the present invention can be employed as photovoltaic device, such as a solar cell. Please refer to FIG. 1, FIG. 3 and FIG. 8B. The electrical circuit 400 further comprises an electrical storage element (not shown). The control method of the semiconductor nanowire solid state optical device of the present invention comprises steps of:
Step 830, twisting the nanowire 100 by the mechanical micro device 500 to form the highest occupied molecular orbital (electron hole), the lowest unoccupied molecular orbital (electron) in the nanowire 100;
Step 840, shining the nanowire 100 with light to cause the nanowire 100 to generate an electric current for charging the aforesaid electrical storage element.

As aforementioned, the mechanical micro device is employed as a switch of the solid state optical device according to the present invention. Once the external force applied to the nanowire is erased, the solid state optical device of the present invention, which is employed as a photovoltaic device or an electroluminescence device becomes in the state of a not semiconductor. Moreover, the advantages of the solid state optical device according to the present invention are: Doping or fabrication of heterostructure to form a semiconductor optical device with a PN interface is necessary in prior arts. However, the nanowire of the present invention is fabricated by a single material. The material can be selected from group 2 elements, triels, tetrels and pentels. According to the present invention, merely twisting the nanowire, a nanowire semiconductor with PN interface can be achieved.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A semiconductor nanowire solid state optical device, comprising:
a nanowire, having a first end and a second end;
a first electrode, coupled to the first end;
a second electrode, coupled to the second end;
an electrical circuit, coupled to the first electrode and the second electrode; and
a mechanical micro device, conjuncted with the nanowire for applying an external force thereto to form highest occupied molecular orbital and lowest unoccupied molecular orbital in the nanowire.

2. The semiconductor nanowire solid state optical device according to claim 1, wherein the nanowire is fabricated by a single material.

3. The semiconductor nanowire solid state optical device according to claim 1, wherein a material of the nanowire is selected from group 2 elements, triels, tetrels and pentels.

4. The semiconductor nanowire solid state optical device according to claim 1, wherein the mechanical micro device applies the external force to twist the nanowire.

5. The semiconductor nanowire solid state optical device according to claim 1, wherein the mechanical micro device comprises an electrical storage element and the nanowire is a photovoltaic device.

6. The semiconductor nanowire solid state optical device according to claim 1, wherein the electrical circuit applies electrical power to the nanowire and the nanowire is an electroluminescence device.

7. A control method of a semiconductor nanowire solid state optical device, comprising a nanowire, an electrical circuit and a mechanical micro device, conjuncted with the nanowire, the control method comprising: applying an external force to the nanowire by the mechanical micro device to form highest occupied molecular orbital and lowest unoccupied molecular orbital in the nanowire.

8. The control method of the semiconductor nanowire solid state optical device according to claim 7, wherein the mechanical micro device applies the external force to twist the nanowire.

9. The control method of the semiconductor nanowire solid state optical device according to claim 7, further comprising a step of applying electrical power to the nanowire for causing the nanowire illuminate.

10. The control method of the semiconductor nanowire solid state optical device according to claim 7, wherein the electrical circuit further comprises an electrical storage element and the control method further comprises a step of shining the nanowire with light to cause the nanowire to generate an electric current for charging the electrical storage element.
